(19) United States
(12) Patent Application Publication
(10) Pub. No.: US 2008/0170393 A1
(43) Pub. Date: Jul. 17, 2008

(54) Adjustable illumination device

(75) Inventor: Yuan-Cheng Chin, San Chung City (TW)

Correspondence Address: TROXELL LAW OFFICE PLLC, SUITE 1404, 5205 LEESBURG PIKE, FALLS CHURCH, VA, 22041, US

(73) Assignee: Unity Opto Technology Co., Ltd.

(21) Appl. No.: 11/652,661

(22) Filed: Jan. 12, 2007

(51) Int. Cl. H01L 29/861

(52) U.S. Cl. 362/231; 257/E33.053

(57) ABSTRACT

An adjustable illumination device comprises a control circuit board, several light-emitting diodes connected to the control circuit board, and a color sensor electrically connected to the control circuit board, wherein every light-emitting diode comprises at least a red chip, at least a blue chip, and at least a green chip, and the color sensor detects and adjusts the light-emitting diodes so as to obtain required light color and maintain stable light color.

### FIELD OF THE INVENTION

The present invention relates to an adjustable illumination device capable of adjusting light color, and more particularly to a light-emitting diode or the like applicable to illumination.

### BACKGROUND OF THE INVENTION

Light-emitting diodes (LEDs) have been widely applied to indicators or light sources of household electric appliances and all kinds of instruments because of their advantages of long lifetime, small size, high vibration endurance, and low power consumption. In the recent years, the light-emitting diodes that generate multiple colors and high brightness are disclosed. Furthermore, the light-emitting diodes are now applicable to large-sized outdoor signboards and traffic lights.

The light-emitting diodes usually emit monochromatic lights such as red lights, green lights, and blue lights. If there is a need to form the mixed light color such as white color, the red, green, and blue light-emitting chips must be packaged into a light-emitting device so as to generate the white light by mixing the red, green, and blue lights via the electric current. However, the obtained light suffers from the problems of non-uniform brightness and hue since every chip has its own optoelectronical property.

In view of the foregoing description, the motive of the present invention is to provide the general public with an adjustable illumination device capable of adjusting light color.

### SUMMARY OF THE INVENTION

It is a major object of the present invention to provide an adjustable illumination device capable of adjusting light color so as to obtain required light color.

In order to achieve the above-mentioned object, an adjustable illumination device is comprised of a control circuit board, several light-emitting diodes connected to the control circuit board, and a color sensor electrically connected to the control circuit board, wherein every light-emitting diode comprises at least a red chip, at least a blue chip, and at least a green chip, and the color sensor detects and adjusts the light-emitting diodes so as to obtain required light color and maintain stable light color.

The other objects and advantages of the present invention will be readily clarified in the description of the preferred embodiments and the enclosed drawings of the present invention.

### BRIEF DESCRIPTION OF THE DRAWINGS

FIG. 1 is an elevational view showing a preferred embodiment of the present invention.

FIG. 2 is a schematic block diagram of circuit showing the preferred embodiment of the present invention.

### DETAILED DESCRIPTION OF THE PREFERRED EMBODIMENT

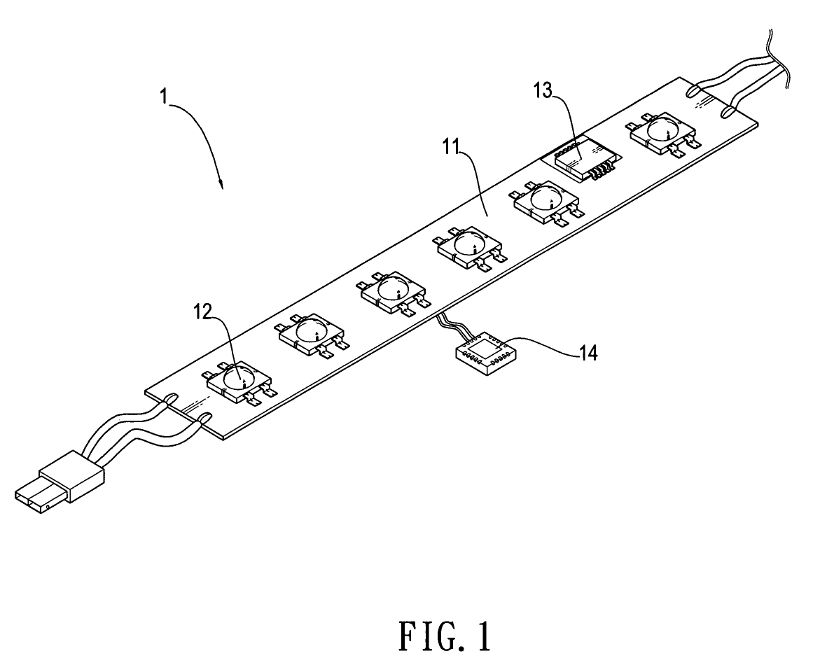

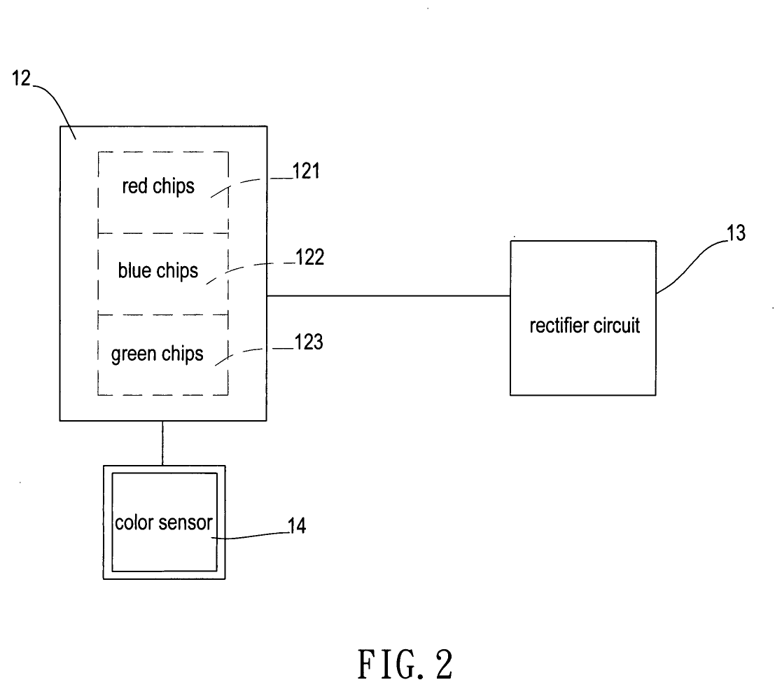

Referring to FIG. 1, an illumination device 1 of the present invention comprises a control circuit board 11, several light-emitting diodes 12, and a color sensor 14. These light-emitting diodes 12 are connected to the control circuit board 11. Each of these light-emitting diodes 12 comprises at least a red chip 121, at least a blue chip 122, and at least a green chip 123, as shown in FIG. 2. The control circuit board 11 is electrically connected to the color sensor 14. In addition, the control circuit board 11 is further connected to a rectifier circuit 13.

After the control circuit board 11 is electrified, the electric current is rectified by the rectifier circuit 13 for being supplied for every element so that the light-emitting diodes 12 and the color sensor 14 can be driven to mix three primary colors emitted from the red chips 121, the blue chips 122, and the green chips 123 to generate the white light. Next, the white light obtained by mixing these three primary colors can be detected by the color sensor 14. Next, the detected data are compared with the pre-established data by the color sensor 14. If they are unmatched, the rectifier circuit 13 adjusts the electric current to supply the respective electric current for the red chips 121, the blue chips 122, and the green chips 123 of the light-emitting diodes 12 so as to enable the red chips 121, the blue chips 122, and the green chips 123 of the light-emitting diodes 12 to emit respective proper-proportioned light colors, whereby the required light color can be obtained by mixing these proper-proportioned light colors. As a result, by using the color sensor 14 for detection and comparison, these light-emitting diodes 12 can emit white lights of different color tones so as to satisfy requirements for use.

Furthermore, the color sensor 14 can further detect the luminous wavelengths of the light-emitting chips including the red chips 121, the blue chips 122, and the green chips 123 so as to duly adjust the proportion of luminous wavelengths to luminous intensity of the light-emitting chips. As a result, the obtained light color will not be affected by the variation of luminous wavelengths of the light-emitting chips. Accordingly, the light-emitting diodes 12 are capable of keeping identical light color after long-term use.

In accordance with the foregoing description, the present invention has the following advantages:

1. The color sensor detects the luminous wavelengths of the light-emitting diodes synchronously and compares the detection results with the originally established data. If they are unmatched, the required light color can be still obtained by using the rectifier circuit 13 to rectify the electric current.

In summary, the adjustable illumination device of the present invention indeed achieves the anticipated objects. Accordingly, the present invention satisfies the requirement for patentability and is therefore submitted for a patent.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments, which do not depart from the spirit and scope of the invention.

What the invention claimed is:

1. An adjustable illumination device comprising:
a control circuit board;
a plurality of light-emitting diodes connected to said control circuit board, each comprising at least a red chip, at least a blue chip, and at least a green chip; and
a color sensor electrically connected to said control circuit board, wherein said color sensor detects and adjusts said light-emitting diodes so as to obtain required light color and maintain stable light color.

2. An adjustable illumination device of claim 1, further comprising a rectifier circuit mounted on said control circuit board.
